(19) United States
(12) Patent Application Publication
(10) Pub. No.: US 2025/0259910 A1
(43) Pub. Date: Aug. 14, 2025

(54) INTEGRATED CIRCUIT PACKAGE WITH MULTI-CHAMBERED THERMAL CONTROL DEVICE

(71) Applicant: XILINX, INC., San Jose, CA (US)

(72) Inventors: Gamal REFAI-AHMED, Santa Clara, CA (US); Chi-Yi CHAO, New Taipei City (TW); Md Malekkul ISLAM, Santa Clara, CA (US)

(21) Appl. No.: 18/970,665

(22) Filed: Dec. 5, 2024

Related U.S. Application Data
(60) Provisional application No. 63/552,497, filed on Feb. 12, 2024.

(51) Int. Cl. H01L 23/427; H01L 23/40; H01L 25/065

(52) U.S. Cl. CPC H01L 23/427; H01L 23/4012; H01L 25/0652

(57) ABSTRACT

Disclosed herein are thermal control devices suitable for thermally regulating chip packages, and electronic devices having the same. In one example, a multi-cavity thermal control device is provided that includes a body having a center cavity disposed between inlet and outlet cavities. The inlet cavity has an inlet port formed proximate a first side of the body. The outlet cavity has an outlet port formed proximate a second side of the body. The center cavity has an inlet coupled to an outlet of the inlet cavity. The inlet of the center cavity is disposed closer to a center of the center cavity than an edge of the center cavity. The center cavity has an outlet configured to flow fluid into the outlet cavity.

### CROSS REFERENCE TO RELATED APPLICATION

This application claims priority to the U.S. Provisional Patent Application Ser. No. 63/552,497 filed Feb. 12, 2024 of which is incorporated herein by reference in its entirety.

### TECHNICAL FIELD

Embodiments of the present invention generally relate to thermal control devices suitable for thermally regulating chip packages, and electronic devices having the same.

### BACKGROUND

Electronic devices, such as tablets, computers, copiers, digital cameras, smart phones, control systems, automated teller machines, data centers, artificial intelligence system, and machine learning systems among others, often employ electronic and/or photonics components which leverage chip packages for increased functionality and higher component density. Conventional chip packaging schemes often utilize a package substrate, often in conjunction with a through-silicon-via (TSV) interposer substrate and/or other such as FanOut and/or passive silicon bridges and/or substrate with glass and/or Si and/or organic core, to enable a plurality of integrated circuit (IC) dies to be mounted to a single package substrate. The IC dies are mounted to a top surface of the package substrate while a bottom surface of the package substrate is mounted to a printed circuit board (PCB).

In many applications, memory dies are integrated into the chip package to reduce the distance between the memory dies and compute dies of the chip package. The shortened distance reduces power consumption and increases device performance. One type of chip package having both a stack of memory dies and at least one connected compute die is known as a high bandwidth memory (HBM). The HBM stack conventionally includes an I/O buffer die upon which the memory dies are stacked. The I/O buffer die also includes the memory controller. However, in most conventional chip packages having a HBM die stack generally have compute dies that have complex route between each compute die and the I/O buffer and memory dies of a particular HBM die stack, often requiring routing through the package substrate. The complex routing creates scheduling complexity that slows device performance. Additionally, the complex routing often requires a larger, more expensive interposer and package substrate to accommodate the increased number of routing traces without generating excessive unwanted noise. The larger interposers and package substrates increase the manufacturing complexity and cost, and contribute to slower performance, which are all undesirable.

Additionally, with the added complexity of such chip packages, providing adequate thermal regulation to the various electronic components within the chip package has become increasingly challenging. Failure to adequately cool the integrated circuit components within the chip package may undesirably lead to premature failure and/or diminished performance.

Therefore, a need exists for improved thermal control devices for chip packages.

### SUMMARY

Disclosed herein are thermal control devices suitable for thermally regulating chip packages, and electronic devices having the same. In one example, a multi-cavity thermal control device is provided that includes a body having a top surface, a bottom surface, a first side facing away from a second side, and a third side facing away from a fourth side. An inlet cavity is formed in the body proximate the first side and has an inlet port formed proximate the first side that is formed through an exterior surface of the body. An outlet cavity is formed in the body proximate the second side and has an outlet port formed proximate the second side through the exterior surface of the body. A center cavity formed is in the body between the inlet and outlet cavities. The center cavity has an inlet coupled to an outlet of the inlet cavity. The inlet of the center cavity is disposed closer to a center of the center cavity than an edge of the center cavity. The center cavity has an outlet configured to flow fluid into the outlet cavity.

In another example, a multi-cavity thermal control device is provided that includes a body having a top surface, a bottom surface, a first side facing away from a second side, and a third side facing away from a fourth side. An inlet cavity is formed in the body proximate the first side and has an inlet port formed proximate the first side that is formed through an exterior surface of the body. An outlet cavity is formed in the body proximate the second side and has an outlet port formed proximate the second side through the exterior surface of the body. The inlet cavity is fluidly connected to the outlet cavity. A center cavity formed is in the body between the inlet and outlet cavities. The center cavity is sealingly isolated from the inlet and outlet cavities, and contains a phase change material.

In yet another example, an electronic device is provided that includes a chip package interfaced with a multi-cavity thermal control device as described herein.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a schematic sectional view of one example of an electronic device that includes a chip package interfaced with a multi-cavity thermal control device.

FIG. 2 is an enlarged partial schematic sectional view of a portion of the chip package of FIG. 1 illustrating the interface between the memory stack, the logic device, and the active silicon bridge.

FIG. 3 is a schematic sectional view of another example of a chip package having an active silicon bridge, a logic device and memory stack that can be incorporated in the electronic device of FIG. 1.

FIG. 4 is a schematic sectional view of another example of a chip package having an active silicon bridge, a logic device and memory stack that can be incorporated in the electronic device of FIG. 1.

FIG. 5 is a schematic plan view of the chip package of FIG. 1.

FIG. 6 is a schematic plan view of another variation of a chip package that can be incorporated in the electronic device of FIG. 1.

FIG. 7 is a schematic block diagram of illustrating on example of an active interposer die of a logic device interfaced with memory stacks and logic devices that can be incorporated in the chip package of FIG. 1.

FIGS. 8-10 are schematic plan views of different configurations of a logic device illustrating exemplary compute die stacks that can be incorporated in the chip package of FIG. 1.

FIG. 11 is an exploded view of one example of the electronic device of FIG. 1 that includes a chip package interfaced with a multi-cavity thermal control device.

FIGS. 12-19 are various views of one example of a heat transfer plate of the multi-cavity thermal control device of FIG. 1.

FIGS. 20-23 are various views of another example of a heat transfer plate of the multi-cavity thermal control device of FIG. 1.

FIG. 23 is a schematic fluid flow schematic of the multi-cavity thermal control device of FIG. 1.

FIG. 24 is another schematic fluid flow schematic of the multi-cavity thermal control device of FIG. 1 for examples wherein the center cavity is configured as a vapor chamber.

To facilitate understanding, identical reference numerals have been used, where possible, to designate identical elements that are common to the figures. It is contemplated that elements of one embodiment may be beneficially incorporated in other embodiments.

### DETAILED DESCRIPTION

Disclosed herein are chip packages and electronic devices that utilize an active silicon bridge having one or more IP blocks, such as a memory controller, to provide a signal interface between a logic device having at least one compute die and one or more memory stacks or other logic device within a singular chip package. The active silicon bridge may also many metal layers for die to die connections, and through silicon vias (TSVs) for vertical connections to the substrate as well as decoupling capacitors. such as metal insulator metal (MIM) capacitors. The chip packages leverage a 2.5D/3D architecture where the active silicon bridge used for lateral die-to-die connections that includes functional circuitry formed in a physical layer (PHY). In some example, the functional circuitry formed in a physical layer (PHY) may be configured as a universal chiplet interconnect express (UCle) PHY, thus enabling the transistors needed for die-to-die connection in the PHY to be relocated from the connected compute die, such as an CPU/GPU SOC, to the active silicon bridge.

The active silicon bridge architecture enables efficient multiple levels of integrated circuit (IC) compute dies stacked to form a logic device. Performance may be further gained through the use of hybrid bonding between the IC compute dies of the logic device. Active interposers further enable multiple stacks of compute dies within a single logic device. The compute dies may be configured as CPUs and/or GPUs as needed to provide flexibility between package configurations.

The active silicon bridge architecture enables the logic device to be efficiently connected to one or more adjacent memory stacks and/or an input/output (I/O) die. The active silicon bridge extends below both the logic device and at least one memory stack to efficiently position die-to-die PHY (such as UCle) for improved performance and lower overall costs. The active silicon bridge architecture may optionally include external I/O PHY (DDR, PCle, etc.) in a location close to the package substrate that reduces routing congestion. The active silicon bridge architecture may alternatively be utilized to efficiently connect two logic devices in close proximity within the chip package to reduce routing congestion and improve performance.

The active silicon bridge architecture also improves logic device yield by moving the analog PHY out of the logic device and into the active silicon bridge. The active silicon bridge architecture also avoids need for custom memory stacks by including off-package memory PHYs in the active silicon bridge. Since the active silicon bridge may be more cost effectively produced relative to other components (e.g., IC dies) of the chip package, standard chiplet designs may be used across a greater number of chip package configurations. Moreover, the modular arrangement of the active silicon bridge, memory stacks and logic device makes the chip package readily scalable and customizable without the need for additional tapeouts. The number and position of the modular arrangement components of the chip package may be selected and arranged for various compute applications without the need for new die or interposer designs. As a result, the chip package provides increased application flexibility at reduced manufacturing costs.

The active silicon bridge generally includes memory controller circuitry disposed below the memory stack. The location of the memory controller circuitry below the memory stack shortens routing, allowing improved transmission speeds and lower power consumption. Furthermore, each active silicon bridge may be configured to interface with one or more memory stacks and one or more compute dies of the logic devices more efficiently as compared to conventional chip packages, resulting in a scalable, robust, and cost efficient design.

In one example, a chip package is provided that includes a substrate, an active silicon bridge, a logic device, and a memory stack. The logic device and the memory stack are mounted over the substrate. The logic device is communicatively coupled to the memory stack via the active silicon bridge that may be mounted above or below the logic device and the memory stack.

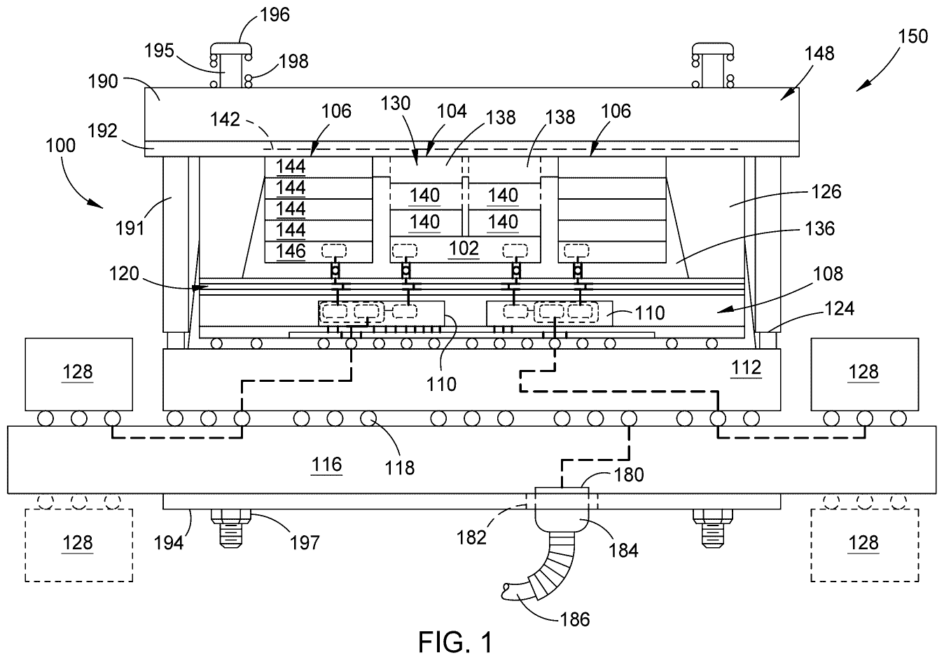

Turning now to FIG. 1, a schematic sectional view of one example of a chip package 100 is provided. The chip package 100 is shown mounted to a printed circuit board (PCB) 116 to form an electronic device 150. The chip package 100 may be configured to mate with corresponding pins of a socket mounted on the PCB 116 to form the electronic device 150. Alternatively and as illustrated in FIG. 1, solder balls 118 may be used to connect the exposed bond pads on the bottom surface of the package substrate 112 to the PCB 116 to form the electronic device 150.

The PCB 116 may optionally have one or more memory devices 128 that are mounted to the PCB 116. Memory devices 128 are shown are mounted to the top surface the PCB 116 in FIG. 1. However, memory devices 128 may also be additionally or alternatively mounted to the bottom surface the PCB 116. The memory device 128 may include one or more memory dies configured as volatile and/or non-volatile memory. In one example, the memory device 128 includes at least one memory die configured as volatile memory. One example of volatile memory is double data rate synchronous dynamic random-access memory (DDR SDRAM). In other examples, the memory devices 128 may be located remote from the electronic device, but can be assessed by components of the chip package 100 by signal transmission routed though the PCB 128 to the chip package 100.

The chip package 100 includes at least one integrated circuit (IC) die mounted on a package substrate. The IC die may be a memory IC die, a logic (processor) IC die, or an optical IC die. The chip package 100 may include only one or more memory IC dies, one or more logic IC dies, or one or more optical IC dies. The chip package 100 may include one or more memory IC dies and one or more logic IC dies; one or more memory IC dies and one or more optical IC dies; one or more logic IC dies and one or more optical IC dies; or one or more memory IC dies, one or more logic IC dies and one or more optical IC dies, or other combination of IC dies and/or types of IC die or dies. The at least one IC die is interfaced with a thermal management device 148, as further described below.

In the example depicted in FIG. 1, the chip package 100 includes at least one active silicon bridge 110, at least one logic device 104, and at least one memory stack 106. The at least one memory stack 106 may alternatively be a second logic device 104. The active silicon bridge 110 provides on package communication between the logic device 104 and the memory stack 106 (and/or second logic device 104). The logic device 104 includes at least one compute die 140, which includes logic circuitry. Although two logic devices 104 are illustrated in FIG. 1, the chip package 100 may include one to as many logic devices 104 as space permits to achieve desired functionality. Similarly, the chip package 100 illustrated in FIG. 1 may include one to as many memory stacks 106 as space permits to achieve desired functionality.

The memory stack 106 includes a buffer die 146 having one or more memory dies 144 stacked thereon. The memory stack 106 is generally mounted adjacent the logic device 104. Each memory stack 106 is generally connected with the adjacent logic device 104 via the active silicon bridge 110. In some examples, more than one memory stack 106 may be connected with a common adjacent logic device 104 via a single active silicon bridge 110 or multiple active silicon bridges 110.

In the exampled depicted in FIG. 1, one or more memory stacks 106 are directly connected to the adjacent logic device 104 via a high bandwidth routing formed in the active silicon bridge 110. The active silicon bridge 110 may be disposed above or below the one or memory stack 106, and in one example, is disposed in the interposer layer 108 residing below the connected memory stack 106 and logic device 104.

As discussed above, each of the memory stacks 106 includes a plurality of stacked memory dies 144. Using the plane of the package substrate 112 as a horizontal reference, the memory dies 144 are vertically stacked. The memory dies 144 within each memory stack 106 can be interconnect via solder interconnect, via hybrid bonding, or other suitable technique. The memory dies 144 within a common memory stack 106 may be volatile memory, such as static random-access memory (SRAM), dynamic random-access memory (DRAM) or other suitable volatile memory type. Optionally, one or more of the memory dies 144 within a common memory stack 106 may be non-volatile memory, such as ferroelectric random-access memory (FeRAM) and magnetoresistive random-access memory (MRAM) or other suitable non-volatile memory type. The memory types of the memory dies 144 of one memory stack 106 may be the same or different than the memory types of the memory dies 144 of another memory stack 106 adjacent a common logic device 104, or another memory stack 106 disposed in another region of the chip package 100 and adjacent a different logic device 104 of the chip package 100.

The number of memory dies 144 within common memory stack 106 may range from 2 to as many as desired. In one example, the number of memory dies 144 within common memory stack 106 is 4 to about 16. The number of memory dies 144 within different memory stacks 106 of the chip package 100 typically are the same. However, memory stacks 106 having different numbers of memory dies 144 may be utilized. When memory stacks 106 having different numbers of memory dies 144 are utilized, the memory stacks 106 may be configured to have the same height. For example, the height difference between stacks 106 may be compensated for by using memory dies 144 having different thicknesses and/or the use of one or more dummy dies on top of the memory stack 106.

The buffer die 146 is generally located at the bottom of the memory stack 106, between the memory dies 144 and the package substrate 112. The buffer die 146 includes I/O circuitry. In another example, the buffer die 146 of the memory die stack 106 may also include a volatile or non-volatile memory circuitry. The buffer die 146 can be interconnect with the overlying memory die 144 via solder interconnect, via hybrid bonding, or other suitable technique.

The logic device 104 includes at least one compute die 140, which may optionally be arranged in one or more compute die stacks 130. When more than one compute die stacks 130 are used in a common logic device 104, the die stacks 130 are mounted on a common IC interposer die 102. In the example depicted in FIG. 1, two compute die stacks 130 are shown. However, additional compute die stacks 130 may be present in a single chip package 100. Each compute die stack 130 includes at least one compute die 140. In the example depicted in FIG. 1, each compute die stack 130 include a two or more compute dies 140.

Compute dies 140 within a common compute die stack 130 may be the same type of die or a different type of processor die. The compute dies 140 within a compute die stack 130 of one logic device 104 of the chip package 100 may be the same type of processor die or a different type of processor die than a compute die 140 in another compute die stack 130 included in the same logic device 104. Similarly, compute dies 140 within one logic device 104 of the chip package 100 may be the same type of processor die or a different type of processor die than another compute die 140 included in the another logic device 104 included in the same chip package 100.

The compute dies 140 are electrically and mechanically coupled to the IC interposer die 102 by interconnects, such as solder bumps, hybrid bonding, or other suitable technique. In the example depicted in FIG. 1, the compute die 140 is hybrid bonded to the IC interposer die 102. Similarly, the compute die 140 is electrically and mechanically coupled to the adjacent compute die 140 in the compute die stack 130 by interconnects, such as solder bumps, hybrid bonding, or other suitable technique. In the example depicted in FIG. 1, the compute dies 140 are hybrid bonded together. As discussed above, hybrid bonded desirably improves communication speeds and allows for increased bandwidth. Moreover, hybrid bonding allows for compute dies having different configurations of bond pad locations to be mounted on the same IC interposer die design since the bond pad in the hybrid bonding layer may be easily relocated without need for a different IC interposer die.

In one example, the functional circuitry of all of the compute dies 140 within a common logic device 104 include central processing unit (CPU) cores. As such, each of the compute dies 140 may be referred to as a CPU die or CPU chiplet. The functional circuitry of the compute dies 140 may also include System Management Unit (SMU). The SMU is circuitry configured to monitor thermal and power conditions and adjust power and cooling to keep the dies 140 functioning as within specifications. The functional circuitry of the compute dies 140 may also include Dynamic Function exchange (DFX) Controller IP circuitry. The DFX circuitry provides management of hardware or software trigger events. For example, the DFX circuitry may pull partial bitstreams from memory and delivers them to an internal configuration access port (ICAP). The DFX circuitry also assists with logical decoupling and startup events, customizable per Reconfigurable Partition.

In another example, the functional circuitry of all of the compute dies 140 within a common logic device 104 include accelerated compute cores. As such, each of the compute dies 140 may be referred to as an accelerator die or accelerator chiplet. The compute dies 140 may also be referred to as a graphic processing unit (GPU) die or GPU chiplet. The accelerated compute cores contained in the functional circuitry of the compute dies 140 generally includes math engine circuitry. The math engine circuitry is generally designed for task specific computing, such as used data center computing, high performance computing and Al/ML computing. Along with the accelerated compute cores, functional circuitry of the compute die 140 may also include SMU circuitry and DFX circuitry.

In other examples, the functional circuitry of at least two of the compute dies 140 within a common logic device 104 are different. For example, one compute die 140 may include accelerated compute cores, while another compute die 140 within a common logic device 104 includes CPU cores. In another example, one or more compute dies 140 present in a common compute die stack 130 may include CPU cores and/or an accelerated compute cores. In yet another example, one or more compute dies 140 present in a first compute die stack 130 may include CPU cores and/or an accelerated compute cores, while one or more compute dies 140 present in a second compute die stack 130 within a common logic device 104 may include CPU cores and/or an accelerated compute cores, wherein the types of compute dies 140 within the first and second compute die stacks 130 may have the same or different arrangement of compute die types.

The logic device 104 may additionally include a carrier die 138 disposed over the compute die stacks 130. The carrier die 138 generally is the top die in the logic device 104, located farthest from the package substrate 112. The carrier die 138 is generally a block of silicon material that provides good heat transfer out of the logic device 104. The carrier die 138 may be thicker than the compute dies 140, thus providing increased structural rigidity and increase resistance to warpage within the logic device 104, which makes connections between compute dies 140 more reliable and robust. The carrier die 138 may be circuit free, i.e., free from routing, passive and active circuit devices. The carrier die 138 is adhered to one or both of the compute die stacks 130. The carrier die 138 may be adhered to the compute die(s) using any suitable adhesive or technique. In one example, the carrier die 138 is fusion bonded to the compute die(s). In such an example, an oxide layer is disposed between the carrier die 138 and the compute die(s) to enhance the fusion bonding process. Fusion bonding increases the structural rigidity of the logic device 104, and makes connections between compute dies 140 more reliable and robust. Optionally, a single carrier die 138 may span more than one logic device 104.

The logic device 104 may additionally include a dummy die (not shown) disposed over or next to one or more of the compute dies 140. The dummy die generally is between the carrier die 138 and the IC interposer die 102. The dummy die may alternatively contact one of the carrier die 138 and the IC interposer die 102, and also contact one or more of the compute dies 140. The dummy die is generally a block of silicon material that provides good heat transfer through the logic device 104. The dummy die also provide mechanical stability across the width of the logic device 104. The dummy die may be circuit free, i.e., free from routing, passive and active circuit devices. The dummy die is adhered to the overlying and underlying dies (i.e., two of the compute dies 140, IC interposer die 102, and carrier die 138. The dummy die may be adhered to the neighboring overlying and underlying dies using any suitable adhesive or technique. In one example, the dummy die is fusion bonded to the neighboring overlying and underlying dies. In such an example, an oxide layer is disposed between the dummy die and each of the neighboring overlying and underlying dies to enhance the fusion bonding process. As with the carrier die 138, fusion bonding of the dummy die increases the structural rigidity of the logic device 104, and makes connections between compute dies 140 more reliable and robust. Optionally, more than one dummy die may be used in a single logic device 104.

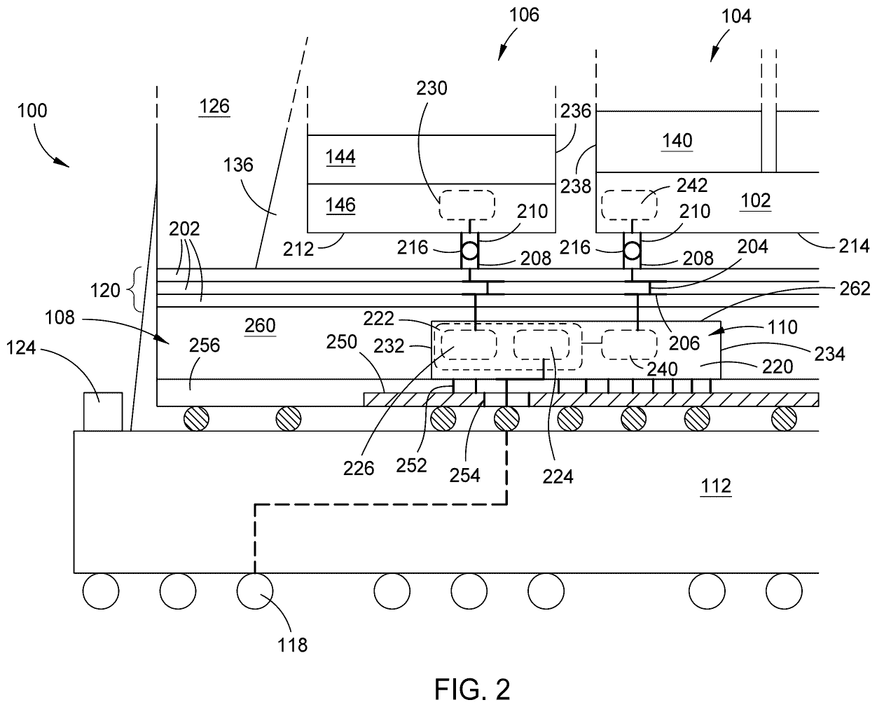

The memory stack 106 and the logic device 104 are disposed above a common package substrate 112. An interposer layer 108 is disposed on and electrically connected to the package substrate 112. The active silicon bridge 110 comprises or resides in the interposer layer 108. The memory stack 106 and the IC interposer die 102 are electrically and mechanically coupled to the interposer layer 108 via an interconnect interface 114. The interconnect interface 114 may include any one or more of solder bumps, hybrid bonding, and a redistribution layer or other type of routing fanout. In the example depicted in FIG. 1, the interconnect interface 114 includes a redistribution layer 120. The redistribution layer 120 is further detailed in FIG. 2.

Continuing to refer to FIG. 1, underfill material 136 may be disposed below the memory stack 106 and the logic device 104 to protect electrical connections and to provide structural strength. Additionally, mold compound 126 may be disposed around the memory stack 106 and the logic device 104. The mold compound 126 provides structural rigidity to the chip package 100, improving warpage resistance while also protecting the electrical components of the chip package 100. The top surfaces of the memory stack 106 and the logic device 104 may be exposed through the mold compound 126 to facilitate interfacing with the thermal management device 148, such as a lid, a heat sink, heat pipe, phase change material, thermal interface material (including liquid metal thermal interface materials), heat spreaders, liquid cooling places, and/or thermal electric cooling plates, among others.

In the exampled depicted in FIG. 1, the thermal management device 148 includes a heat transfer plate 190, a top clamp plate 192 and a bottom clamp plate 194. The top and bottom clamp plates 192, 194 sandwich the chip package 100. In some examples, the top and bottom clamp plates 192, 194 additionally sandwich the PCB 116 along with the chip package 100. The top and bottom clamp plates 192, 194 are urged together by springs 198 that are captured between a head 196 of a fastener 195 and the top surface of the heat transfer plate 190. The fastener 195 extends through the heat transfer plate 190 and the top and bottom clamp plates 192, 194 to engage a nut 197 disposed below the bottom clamp plate 194. Tightening the fastener 195 compresses the spring 198 to control the force that urges the chip package 100 against the bottom surfaces of the top clamp plate 192 and the heat transfer plate 190 as further described below.

The bottom clamp plate 194 additionally includes one or more windows 182. One window 182 is shown in FIG. 1. The window 182 allows a connector 184 of an electrical cable 186 to pass through the bottom clamp plate 194 to engage a mating connector 180 disposed on the bottom of the PCB 116, thus electrically connecting the cable 186 to the chip package 100. In some example, the mating connector 180 may alternatively be disposed on the bottom of the package substrate 112.

The top surfaces of the mold compound 126, the memory stack 106, and the compute die stack 130 may optionally be covered by a metal layer 142 to enhance heat transfer to thermal management device 148. The metal layer 142 may be copper, aluminum, nickel, other suitable material. A thermal interface material (TIM (not shown)) may be disposed between and in contact with the metal layer 142 and underside of thermal management device 148. The TIM may be a liquid metal, phase change material, thermal grease, thermal pad, or other suitable heat transfer material. In one example, the TIM is indium.

Referring now to both FIG. 1 and FIG. 2, the redistribution layer 120 includes routing the electrically connects routing of the interposer layer 108 (which also includes circuitry of the active silicon bridge 110) to the circuitry of the logic device 104 and the memory stack 106. The redistribution layer 120 include a plurality of dielectric layers 202 in which the routing circuitry of the redistribution layer 120 is formed. The routing circuitry of the redistribution layer 120 includes patterned conductive lines 206 connected by vias 204. Not all the routing circuitry of the redistribution layer 120 is shown in FIG. 1 and FIG. 2 to avoid overcrowding the illustrations.

The routing circuitry of the redistribution layer 120 is terminated at an upper end at conductive pillars 208. The conductive pillars 208 may be plated copper or other suitable material. Some of the conductive pillars 208 are connected to conductive pillars 210 formed below and in contact with the conductive pads (not shown) exposed on a bottom surface 214 of the logic device 104 and a bottom surface 212 of the memory stack 106. The pillars 208, 210 are electrically connected by interconnects 216, such as solder microbumps, hybrid bonds, or other suitable technique. Some of routing circuitry of the redistribution layer 120 terminates at a lower end at the conductive pads (not shown) formed on an upper surface of the active silicon bridge 110. Thus, signals may be transferred between the logic device 104 and the active silicon bridge 110 via some of routing circuitry of the redistribution layer 120. Signals may be also transferred between the memory stack 106 and the active silicon bridge 110 via other portions of routing circuitry of the redistribution layer 120.

Referring now primarily to FIG. 2, outer sides 232, 234 of the active silicon bridge 110 horizontally overlaps facing sides 236, 236 the logic device 104 and the memory stack 106. The active silicon bridge 110 is generally a chiplet having a body 220 that contains one or more intellectual property cores (e.g., IP blocks) 222. The IP blocks 222 may include one or more IP blocks 222 selected from the group consisting of Serializer/Deserializers (SerDes), phase-locked loops or phase lock loops (PLLs), digital-to-analog converters (DACs), analog-to-digital converters (ADCs), physical layers (PHYs), central processor units CPUs, direct memory access (DMA) engines, accelerators, and memory controllers, among others. In the example depicted in FIG. 2, the IP block 222 is a memory controller circuitry (hereinafter referred to as memory controller circuitry 222). The body 220 is generally a block of silicon material upon which circuitry and routing is formed. The body 220 also may include through silicon vias for routing ground, power and/or signals from the underside of the active silicon bridge 110. The memory controller circuitry 222 includes off-package memory controller circuitry 224 and on-package memory controller circuitry 226. The off-package memory controller circuitry 224 is generally configured to control communications with memory that is not within (e.g., remote from) the chip package 100. The off-package memory controller circuitry 224 is configured to communicate with memory located within the electronic device 150 that are not within the chip package 100, or with memory located outside of the electronic device 150. In one example, the off-package memory controller circuitry 224 is configured to communicate through the package substrate 112 with the one or more memory devices 128 that are mounted to the PCB 116; or stated differently, memory devices that are located within the electronic device 150 but are not within the chip package 100.

Continuing to refer to FIG. 2, the on-package memory controller circuitry 226 is located in the active silicon bridge 110 below the memory stack 106. In one example, the on-package memory controller circuitry 226 is directly below the memory stack 106. The buffer die 146 of the memory stack 106 includes I/O circuitry 230. The I/O circuitry 230 overlies a portion of the active silicon bridge 110 that includes the on-package memory controller circuitry 226. The on-package memory controller circuitry 226 is also below the memory stack 106. As the I/O circuitry 230 of the buffer die 146 of the memory stack 106 is substantially vertically aligned the on-package memory controller circuitry 226.

In one example, the memory controller circuitry 222 includes one or more of interconnect circuitry, high bandwidth memory attached last level cache (HALL) circuitry, tag circuitry, memory circuitry, memory controller circuitry, memory devices, and direct memory access (DMA) circuitry. The active silicon bridge 110 may include coherency station circuitry that includes N coherency station circuitries. The HALL circuitry includes N HALL circuitries, the tag circuitry includes N tag circuitries, and the memory controller circuitry includes N memory controller circuitries. N is greater than 1. In one example, N is 2, 4, or 8, or more. In one example, each memory die 144 is associated with a respective memory controller circuitry, a respective HALL circuitry, and a respective tag circuitry.

The memory circuitry 222 includes the arbitration circuitry, and memory controller circuitry. In one example, the memory circuitry 222 includes more than one arbitration circuitry and or more than one memory controller circuitry.

In some examples, the memory controller circuitry 222 includes a cache memory. In such an example, local copies of data stored within the memory dies 144 are stored within the cache memory. The tag circuitry maintains tags that associate memory lines and data stored within the memory dies 144 to addresses (e.g., memory lines) within the memory die 144. In one example, the tag circuitry is a static random access memory (SRAM), or another type of memory. As data within the memory die 144 is accessed, copies of the data are stored within a memory die 144 via a respective HALL circuitry and a respective memory controller circuitry. Further, a tag is updated or created within a respective tag circuitry to associate the address (or memory line(s)) of the data within the memory die 144 to the memory address (memory lines) of the data within the external memory device 128. Accordingly, when future memory commands are used to access the memory address, the memory command is forwarded to the memory dies 144 to retrieve the data. As the memory dies 144 have a higher bandwidth than the memory device 128, reading data from the memory dies 144 is faster, increasing the operating speed and decreasing lag of the corresponding system (e.g., the chip package 100 of FIG. 1).

In one example, a read memory command for a first address is provided by the coherency station circuitry and is received by the HALL circuitry. The HALL circuitry accesses the tag circuitry to determine if data associated with the first address is stored within a memory die 144. If a tag within the tag circuitry indicates that the data associated with the first address is stored within a memory die 144, a “hit” is declared and the memory lines of the corresponding memory device 280 is read and the data is output. If a tag within the tag circuitry indicates that the data associated with the first address is not stored within a memory die 144, a “miss” is declared and the read command is provided to the arbitration circuitry, and the memory controller circuitry to access to the memory device 128. The memory line(s) of the memory device 128 associated with the address of the memory command is accessed, and the corresponding data is output to the logic device 104 via the coherency station circuitry. In one example, the data is further stored within one of the memory dies 144, and a corresponding tag within the tag circuitry is updated via the HALL circuitry.

For a write command, the coherency station circuitry provides the write command including an address and data to the HALL circuitry via the interconnection circuitries. The HALL circuitry uses the tags within tag circuitry to determine if the address of the write command is within the memory dies 144. If the address of the write command is associated with an address (e.g., memory lines) of the memory dies 144 (e.g., a “hit”) the data is written to the memory die 144 via the associated address. The data may be written to the corresponding address within the memory device 128 at a later point, reducing latency in the corresponding system. If the address of the write command is determined to not be associated with an address of the memory dies 144 (e.g., a “miss”), the write command is provided to the arbitration circuitry, and the memory controller circuitry to be written to the corresponding memory lines of the external memory device 128. In one example, the memory address of the write memory command and corresponding data is additionally loaded into the memory dies 144 and a tag within the tag circuitry is updated via the HALL circuitry. Accordingly, future access to the requested memory address is sped up as the bandwidth and speed of the memory die 144 is greater than that of the memory device 128. In one or more examples, instead of directly writing to the external memory device 128, when a miss is determined, the memory line(s) of the external memory device 128 associated with the write command is (are) loaded into the memory die(s) 144 and the tags within the tag circuitry is updated. The data of the write command is written to the corresponding memory lines of the memory device(s). In one example, during a write memory command, the data is written to the memory die 144 and a corresponding tag within the TAG circuitry is updated, and an indication is provided to the memory device 128, alerting the memory device 128 to a write to an address within the memory device 128. The memory controller circuitry and/or the memory device 128 may prevent a write or read to the same address until the write command is completed by writing the data from the memory dies 144 to the memory device 128.

In one example, the memory controller circuitry 222 provides one or more memory commands (e.g., read and/or write commands) to the DMA circuitry. The memory commands are provided as pre-fetched, predicted, preliminary, pending, or future memory commands. For example, the on-package memory controller circuitry 226 determines pre-fetched memory commands based on an application executing within the processing circuitry. The pre-fetched memory commands are provided the DMA circuitry before the executed application generates the memory commands. The DMA circuitry and HALL circuitry determines whether or not the addresses and data associated with the predicted memory commands are stored within the memory dies 144 via the tags of the tag circuitry. For addresses that are not found within the memory dies 144, the DMA circuitry, the memory controller circuitry, and the HALL circuitry provide the corresponding memory commands to the memory controller and the memory device 128, to load the corresponding data into memory lines of the memory dies 144. For data that is loaded from the memory device 128 to the memory dies 144, a corresponding tag within the tag circuitry is updated, mapping the memory lines (e.g., memory addresses) of the memory dies 144 to memory lines (e.g., memory addresses) of the memory device 128. Accordingly, when the application running on the memory controller circuitry 222 executes a memory command, the data and address of the memory command is accessible within the memory dies 144, reducing latency and speeding up operation of the corresponding system. In one example, the memory commands provided to the memory controller circuitry and the memory device 128 are scheduled when bandwidth is available within the memory dies 144, further reducing latency within the corresponding computer system, and increasing the speed of the corresponding computer system.

Similarly, the active silicon bridge 110 includes a physical interface layer (PHY) 240 configured to communicate with a physical interface layer 242 of the logic device 104. The physical interface layer 240 is overlapped with the logic device 104. The physical interface layer 242 is overlapped with a portion of the active silicon bridge 110 that is under the logic device. As the physical interface layers 240, 242 are essentially vertically aligned, less space is need for routing, while the short routing distance also improves communication speed and performance.

The chip package 100 may also include an optional metal layer 250 disposed between the active silicon bridge 110 and the package substrate 112. The metal layer 250 may be electrically isolated from the active silicon bridge 110 by a dielectric layer 256. The metal layer 250 extends beyond one or both sides 232, 234 of the active silicon bridge 110. The metal layer 250 functions to route heat generated by the active silicon bridge 110 or other routing below the active silicon bridge 110 laterally outward from below the active silicon bridge 110. As such, the metal layer 250 is not part of the shielding, ground, power or signal transmission circuitry of the chip package 100. Thermal vias 252 formed through the dielectric layer 256 may be utilized to conduct heat from the bottom surface of the active silicon bridge 110 to the metal layer 250. Routing heat laterally away from the active silicon bridge 110 improves the performance and reliability of the functional circuitry residing within the active silicon bridge 110.

The metal layer 250 and dielectric layer 256 also include apertures 254 formed therethrough that allow ground, power and/or signal transmission circuitry to be routed through the metal layer 250 between the circuitry of the package substrate 112 to the circuitry of the active silicon bridge 110. In one example, signal routing passes through apertures 254 formed through the metal layer 250 to connect to the memory devices 128 disposed on the PCB 116. In another example, power routing passes through apertures 254 formed through the metal layer 250 to power to the functional circuitry residing within the active silicon bridge 110.

In the example depicted in FIGS. 1 and 2, the active silicon bridge 110 is disposed in a layer of mold compound 260. The mold compound 260 may be an epoxy, polymer, or other suitable dielectric material. The active silicon bridge 110 is disposed in a cavity 262 formed in the mold compound 260, or may be fully or partially encapsulated in the mold compound 260.

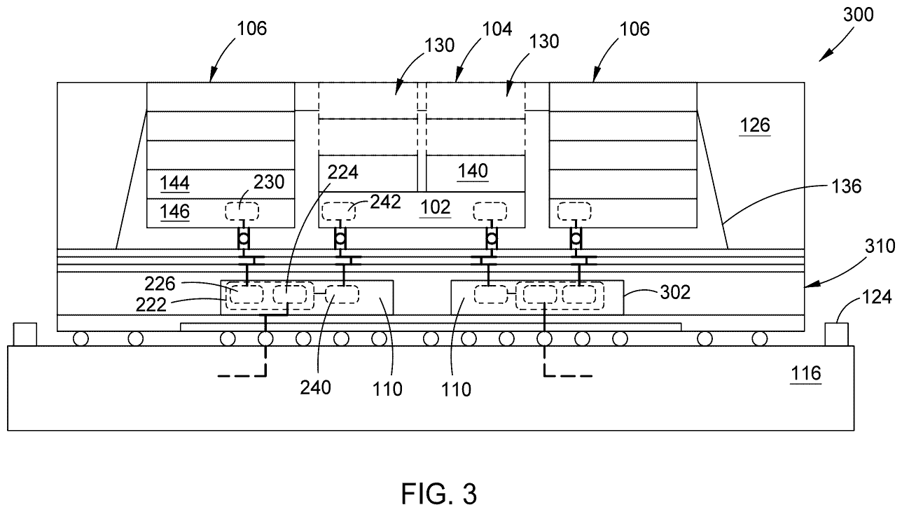

Alternatively as illustrated in another configuration of a chip package 300 depicted in FIG. 3, the active silicon bridge 110 may be disposed in a cavity 302 formed in an interposer 310. The interposer 310 may be formed from a plastic material, glass reinforced plastic, ceramic, glass or other suitable dielectric material. The other components of the chip package 300 are substantially the same as the chip package 100 described above.

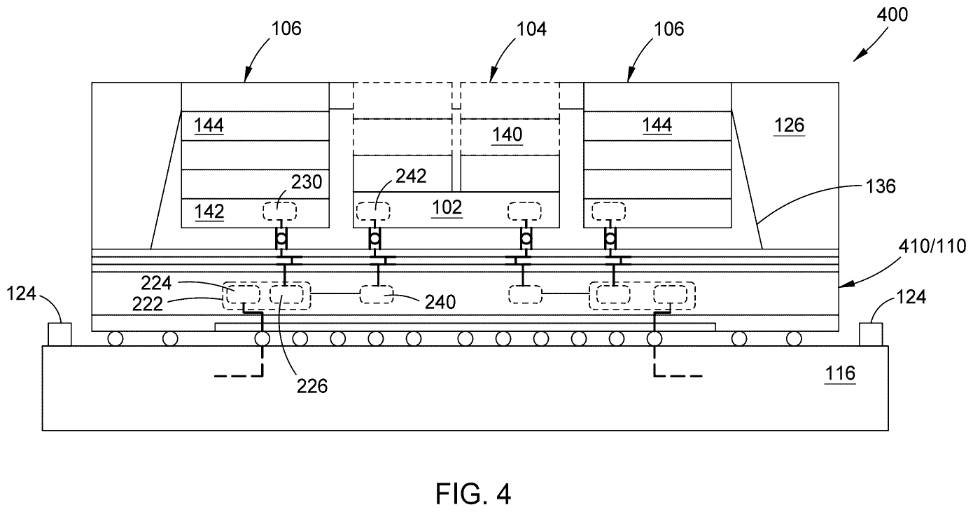

Alternatively as illustrated in another chip package 400 depicted in FIG. 4, the active silicon bridge 110 be configured as an interposer 410. The interposer 410 includes the circuitry of the active silicon bridge 110. Thus, the interposer 410 may be configured as a large silicon die. The other components of the chip package 400 are substantially the same as the chip package 100 described above.

Referring back to FIG. 1, the package substrate 112 may also include surface mounted components 124 that are coupled to the logic device 104 via routing formed through the package substrate 112, the interposer layer 108, the interconnect interface 114, and/or the active silicon bridge 110. The surface mounted components 124 may be integrated passive devices (IPDs), such as capacitors, inductors, and resistors, among others. The surface mounted components 124 may also be power modules. In one example, the surface mounted components 124 are capacitors. In addition or alternatively, some or all of the surface mounted components 124 may be located as IPDs in other locations of the chip package 100. For example, IPDs may be located within or attached to the interposer layer 108, within the package substrate 112, in the redistribution layer 120, or other suitable location within the chip package 100

The package substrate 112 may include an optional stiffener (not shown). The stiffener, when present, has a ring shape surrounds the memory stack 106 and the logic device 104, and the surface mounted components 124. The stiffener may be affixed to the top surface of the package substrate 112, thus making the package substrate 112 and ultimately the chip package 100 less prone to warpage, improving the reliability and performance of the chip package 100.

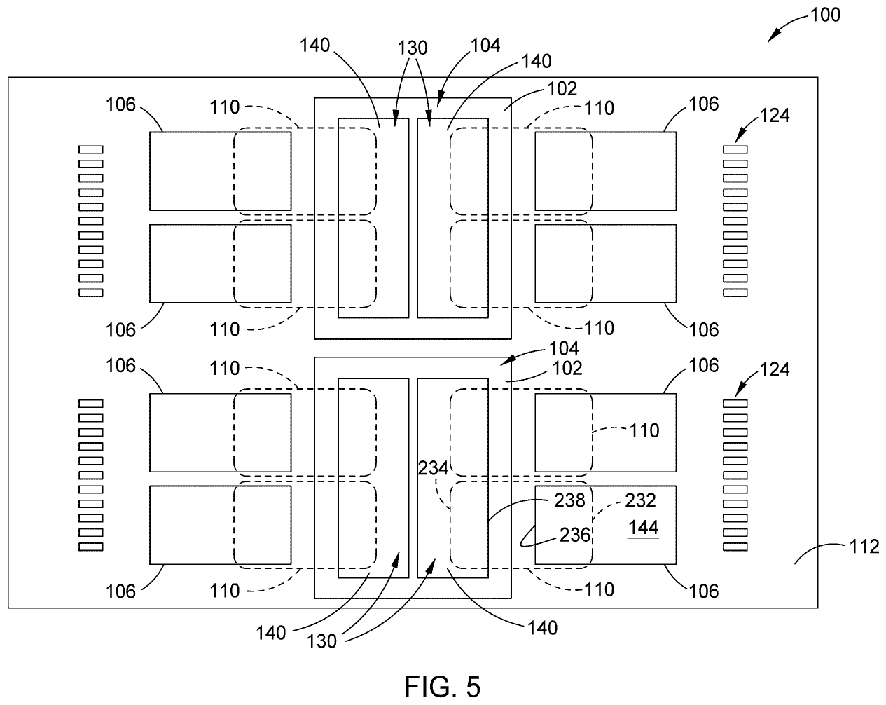

As discussed above, one or more active silicon bridges 110 may be interfaced with one or more logic devices 104. In the top view of the chip package 100 depicted in FIG. 5, each active silicon bridge 110 (shown in phantom) is interfaced with one logic device 104. Each logic device 104 is interfaced with at least one active silicon bridge 110. In the example depicted in FIG. 5, each logic device 104 is interfaced with a plurality of active silicon bridges 110. Similarly, each active silicon bridge 110 may be interfaced with one compute die stack 130 of a common logic device 104. Each compute die stack 130 of a common logic device 104 is interfaced with at least one active silicon bridge 110. In the example depicted in FIG. 5, each compute die stack 130 of a common logic device 104 is interfaced with a plurality of active silicon bridges 110. Additionally, each active silicon bridge 110 may be interfaced with the one or more compute dies 140 of a common logic device 104. The compute dies 140 of a common compute die stack 130 are interfaced with at least one active silicon bridge 110. In the example depicted in FIG. 5, the compute dies 140 of a common compute die stack 130 is interfaced with a plurality of active silicon bridges 110.

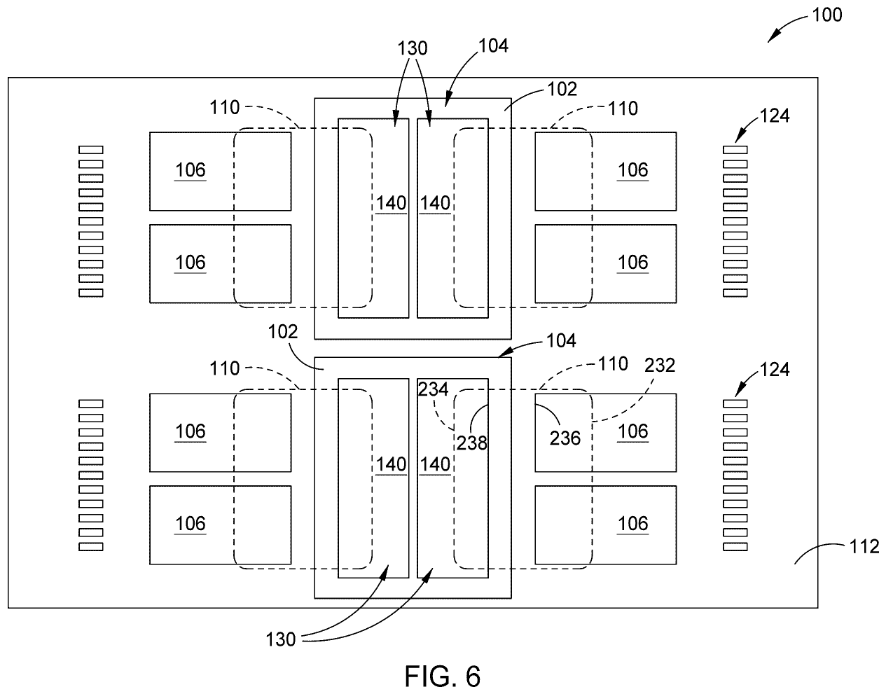

FIG. 6 depicts a variation to the chip package 100 having a first active silicon bridge 110 interfaced with one or more memory stacks 106. The chip package 100 may include one or more other active silicon bridges 110 interfaced with one or more other memory stacks 106. In the top view of the chip package 100 depicted in FIG. 6, each active silicon bridge 110 (shown in phantom) is interfaced with one logic device 104 and two or more memory stacks 106. Each logic device 104 is interfaced with at least one active silicon bridge 110. Each memory stack 106 is interfaced with at least one active silicon bridge 110. In the example depicted in FIG. 6, each logic device 104 is interfaced with a plurality of active silicon bridges 110. Similarly, each active silicon bridge 110 may be interfaced with one compute die stack 130 of a common logic device 104 and two or more memory stacks 106. In other examples where the orientation of the compute die stacks 130 of a common logic device 104 are rotated 90 degrees, each active silicon bridge 110 may be interfaced with one or more compute die stacks 130 of a common logic device 104 and two or more memory stacks 106.

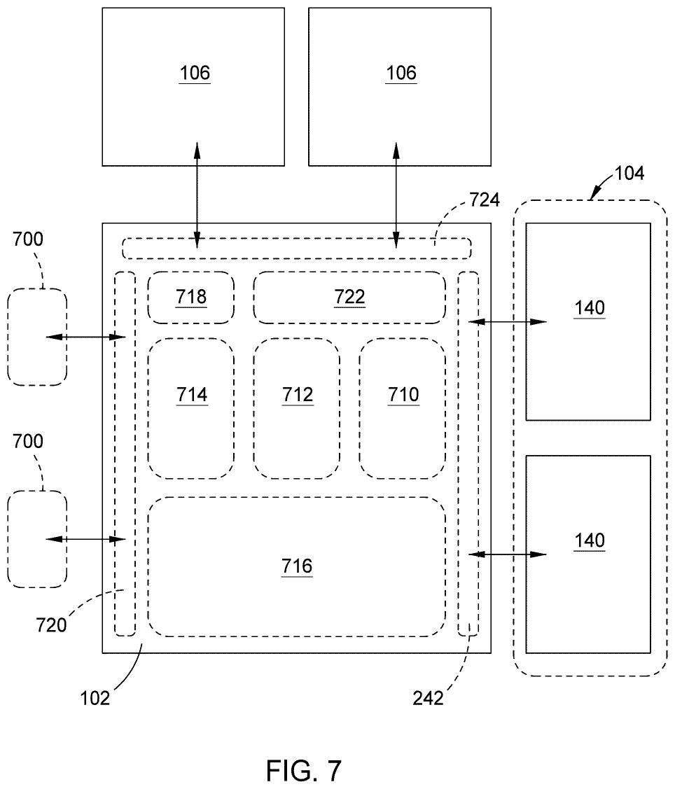

FIG. 7 is a schematic block diagram of one example of the IC interposer die 102 interfaced with one or more memory stacks 106 and one or more compute die stacks 130 that may be utilized in any of the chip packages contemplated herein, such as but not limited to chip packages 100, 300, 400, among others. The IC interposer die 102 may alternatively have other configurations. The functional circuitry of the IC interposer die 102 illustrated in FIG. 7 optionally includes logic circuitry 712 for processing signals passing through the interposer die 102. The functional circuitry of the IC interposer die 102 may also include cache memory circuity 710. The cache memory circuity 710 is coupled to both the compute dies 140 without routing signals through the package substrate 112 or the interposer layer 108. The cache memory circuity 710 provides a large common cache for the compute dies of the compute die stack 130 mounted to the IC interposer die 102.

The functional circuitry of the IC interposer die 102 may also include peripheral component interconnect express (PCle) circuity 714, memory physical layer (PHY) circuitry 724 configured to communicate with the memory stack 106, die to die PHY 722 configured to communicate with at least one or more compute die stacks 130, and I/O PHY 720 configured to communicate with a remove device 700 outside of the chip package 100, or a printed circuit board 116 via the package substrate 112. One example of a remove device 700 may be the memory devices 128. The I/O PHY 720 may also be configured to communicate with other IC interposer dies 102 and/or compute die stacks 104 that are remove from the interposer die 102 in which the I/O PHY 720 resides. The I/O PHY 720 may also be configured to communicate with other memory stacks 106 residing in the chip package 100.

The functional circuitry of the IC interposer die 102 may also include functional block 716 that serializes and deserializes digital data used in high-speed chip-to-chip communication (e.g., serdes circuitry). The functional circuitry of the IC interposer die 102 may also include one or more other functional blocks 718 for performing other functions of a network on a chip (NOC).

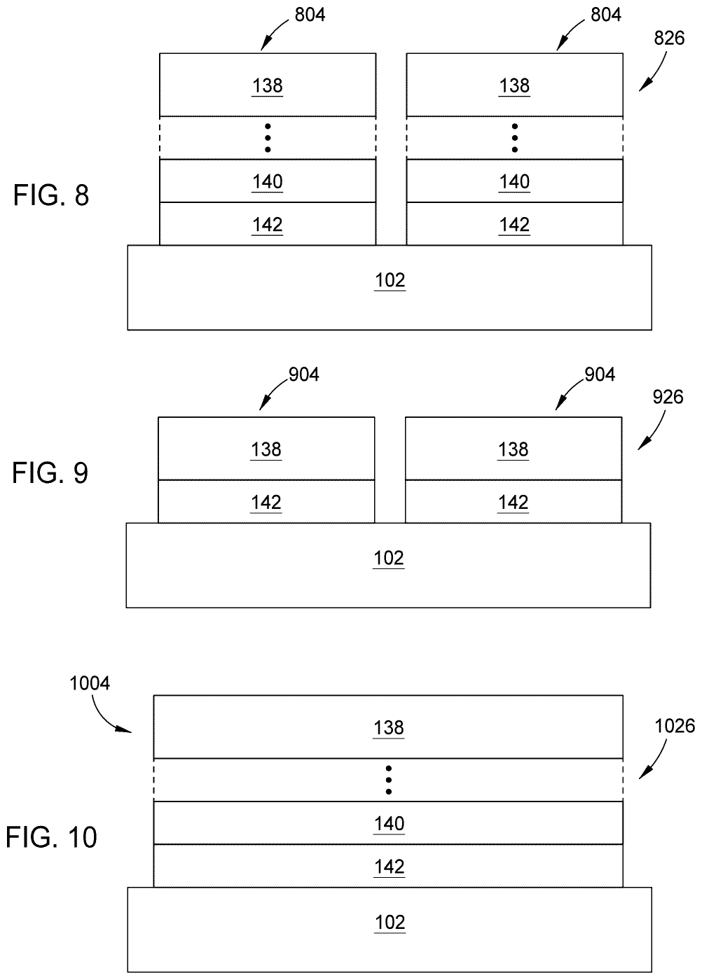

FIG. 8 is a schematic sectional view of one example of a logic device 826. The logic device 826 includes one or more compute die stacks 804 mounted on an IC interposer die 102. Two compute die stacks 804 are shown in FIG. 8, but the compute die stacks 804 may number from 1 to as many as can be reasonably accommodated on the IC interposer die 102. Each of the compute die stacks 804 may include one or more compute dies 140, and optional dummy dies as described above with reference to FIGS. 1 and 2. The logic device 826 may be utilized in any of the chip packages contemplated herein, such as but not limited to chip packages 100, 300, 400, among others.

In the example depicted in FIG. 8, two compute dies 140 are shown in each compute die stack 804. However, there may be none, one or more additional compute dies disposed between the compute die 140 and an optional carrier die 138.

FIG. 9 is a schematic sectional view of one example of a logic device 926. The logic device 926 includes one or more compute die stacks 904 mounted on the IC interposer die 102. Two compute die stacks 904 are shown in FIG. 9, but the compute die stacks 904 may number from 1 to as many as can be reasonably accommodated on the IC interposer die 102. Each of the compute die stacks 904 includes one or more compute dies 140, and may include optional dummy dies as described above with reference to FIGS. 1 and 2. The logic device 926 may be utilized in any of the chip packages contemplated herein, such as but not limited to chip packages 100, 300, 400, among others.

In the example depicted in FIG. 9, each compute die stack 904 includes a single compute die 140. Each compute die 140 is covered by a separate carrier die 138. Optionally, a single carrier die 138 may span to or more of the die stack 904.

FIG. 10 is a schematic sectional view of one example of a logic device 1026. The logic device 526 includes one or more compute die stacks 1004 mounted on an IC interposer die 102. A compute die stack 1004 is shown in FIG. 10, but the compute die stacks 1004 may number from 1 to as many as can be reasonably accommodated on the IC interposer die 102. The compute die stack 1004 includes one or more compute dies 140, and may include optional dummy dies as described above with reference to FIGS. 1 and 2. The logic device 1026 may be utilized in any of the chip packages contemplated herein, such as but not limited to chip packages 100, 300, 400, among others.

In the example depicted in FIG. 10, two compute dies 140 are shown in the compute die stack 1004. However, there may be none, one or more additional compute dies disposed between the compute die 140 and the optional carrier die 138.

Thus, the chip packages disclosed above arrange memory stacks as a unified memory device efficiently available through an active silicon bridge that contains active circuitry. The active silicon bridge couples one or more compute dies to one or more memory stacks. The short routing provided by the active silicon bridge improves speed and performance, while reducing the space needed for complex routing as required in conventional packages. The modular arrangement enabled by the active silicon bridge architecture makes the chip package readily scalable and adapted to be configured for various compute applications without the need for new die or interposer designs. As a result, the chip package provides increased application flexibility at reduced manufacturing costs.

As discussed above, the thermal management device 148 is used to control the temperature of the chip package 100 by removing heat from the chip package 100 through heat transfer plate 190. The efficient remove of heat via the thermal management device 148 enables greater speed, density and performance of the chip package 100, and ultimately the electronic device 150.

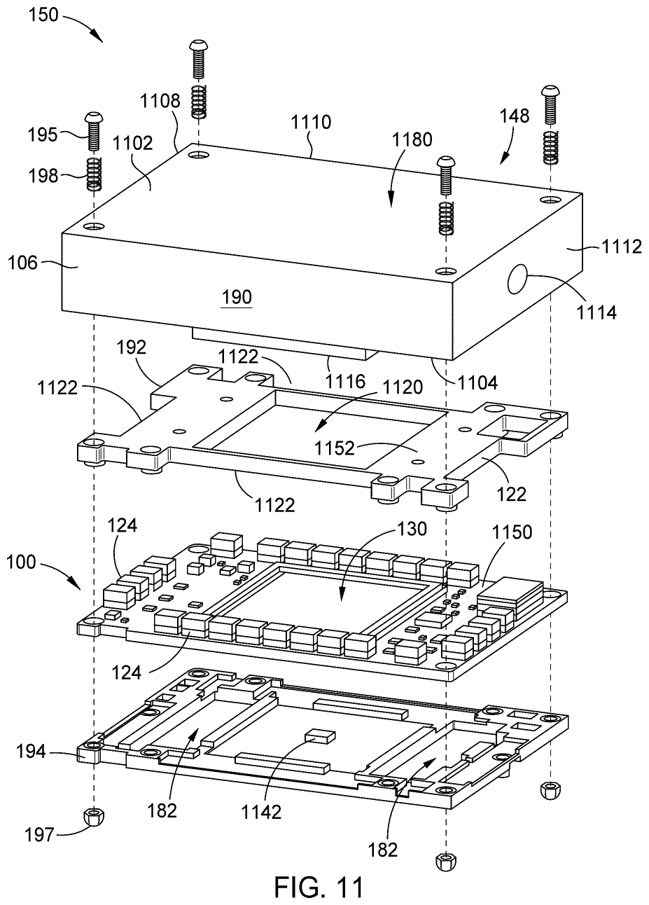

FIG. 11 is an exploded view of one example of the electronic device 150 of FIG. 1 that includes a chip package 100 interfaced with a multi-cavity thermal control device 148. In FIG. 11, the PCB 116 is not shown, but may be optionally present between the chip package 100 and the bottom clamp plate 194.

The heat transfer plate 190 includes a body 1180. The body 1180 may be fabricated as a unitary structure, or may be an assembly of two or more structures. The body 1180 is generally fabricated from a material having good heat transfer properties, such as a metal. Suitable materials for fabricating the body 1180 include, but are not limited to, aluminum, stainless steel, and copper, among others. The body 1180 may also be fabricated from a thermally conductive material having diamond and/or metal particles.

In one example, the metal particles are copper particles. The top clamp plate 192 may be fabricated from similar materials.

The body 1180 a top surface 1102, a bottom surface 1104, a first side 1112 facing away from a second side 1108, and a third side 1106 facing away from a fourth side 1110. An inlet cavity formed in the body 1180 proximate the first side 1112 and has an inlet port 1114 formed proximate the first side 1112. The inlet port 1114 is formed through an exterior surface of the body 1180. An outlet cavity formed in the body 1180 proximate the second side 1106 and has an outlet port formed proximate the second side 1106. The outlet port formed through the exterior surface of the body 1180. A center cavity formed in the body between the inlet and outlet cavities. The center, inlet and outlet cavities are shown in the illustrations that follow.

The bottom surface 1104 of the body 1180 includes a pad 1116 extending therefrom in a direction away from the top surface 1102. The pad 1116 may be integrally formed with the body 1180, or may be a separate component attached to the bottom surface 1104 of the body 1180, for example by braising or suitable technique, as illustrated in the enlargement depicted in FIG. 17. Suitable materials for fabricating the pad 1116 include, but are not limited to, aluminum, stainless steel, and copper, among others. The pad 1116 may also be fabricated from a thermally conductive material having diamond and/or metal particles. In one example, the metal particles are copper particles. The pad 1116 may be formed, in one example, by injection molding, compression molding, additive manufacturing (i.e., 3D printing) or other suitable techniques that allow the diamond and/or metal particles as a filler in the base materials comprising the pad 1116.

The pad 1116 is generally aligned directly below the center cavity and extends through a center window 1120 formed in the top clamp plate 192. The center window 1120 allows the compute die stack 130 that includes at least one compute die 140 to contact the pad 1116 so that the center cavity of the heat transfer plate 190 may more efficiently remove heat from the interior and greater heat generating regions of the chip package 100.

The top clamp plate 192 also includes side windows 1122. The side windows 1122 allow other components of the chip package 100 to be in thermal contact with the heat transfer plate 190 without the heat having to conduct through the top clamp plate 192. In the example depicted in FIG. 11, the side windows 1122 allow surface mounted components 124, such as power modules among others types of components, to be in thermal contact with the heat transfer plate 190 without the heat having to conduct through the top clamp plate 192. As illustrated in FIG. 1, but not shown in FIG. 11, a thermal pad 191 or other high heat conducting material may be disposed between the surface mounted components 124 and the heat transfer plate 190 to facilitate good heat transfer therebetween.

The top clamp plate 192 also a web 1152 formed outward of the center window 1120. The web 1152 is configured to cool peripheral portions of the chip package 100. For example, the tops of the memory stacks 106 or other integrated circuit of the chip package 100 may contact the web 1152 to facilitate remove of heat from those components of the chip package 100 to the heat transfer plate 190 through the web 1152 of the top clamp plate 192. Thermal interface material may be disposed between the web 1152 of the top clamp plate 192 and the adjacent components of the chip package 100.

The bottom clamp plate 192 is shown below the chip package 100 in FIG. 11. The bottom clamp plate 192 includes windows 182 to facilitate electrical connection with the bottom of the chip package 100 or PCB 116. The bottom clamp plate 192 also includes a bumper 1142 that is compressed against the chip package 100 (or PCB 116 when present). The bumper 1142 is centered below the compute die stack 130 so that good thermal contact is maintained between the compute die stack 130 and the heat transfer plate 190. The bumper 1142 may be an elastomer, a spring form or other resilient material.

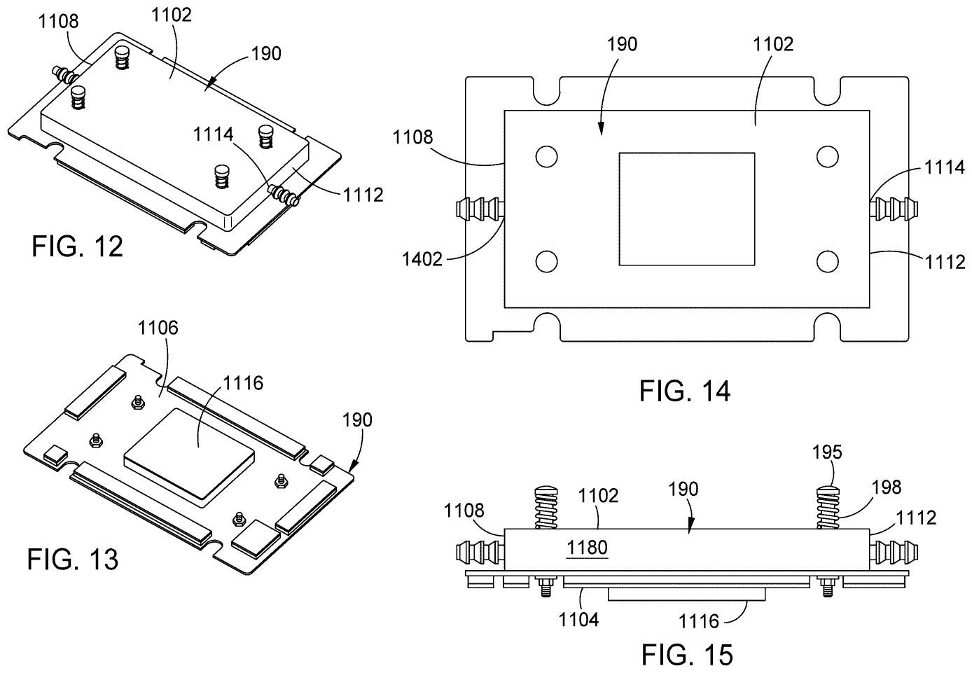

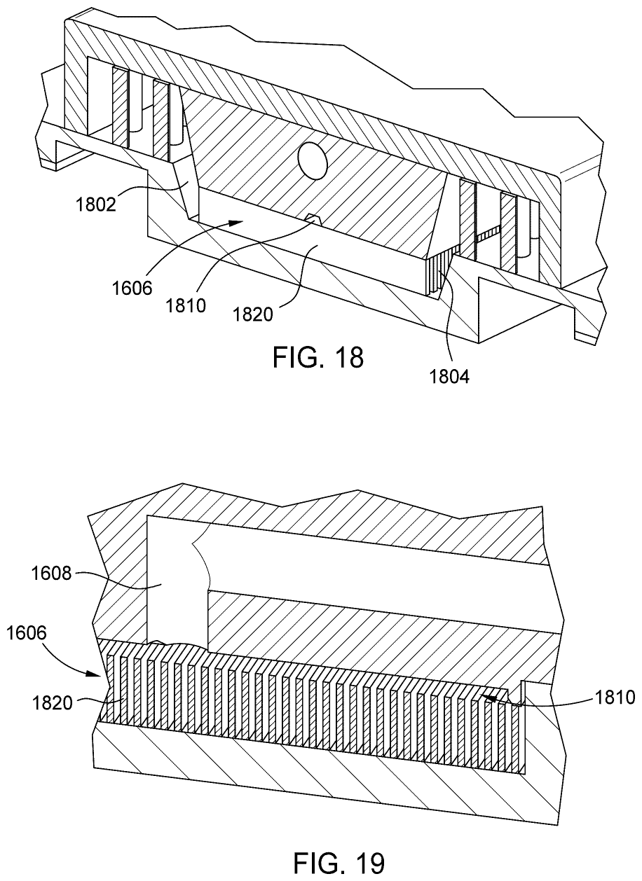

FIGS. 12-19 are various views of one example of a heat transfer plate 190 of the multi-cavity thermal control device 148 of FIG. 1, as also illustrated in FIG. 11. In FIG. 13, the pad 1116 extending from the bottom surface 1106 of the body 1180 of the heat transfer plate 190. In FIGS. 14-15, the outlet port 1402 is more clearly illustrated formed in the second side 1108 of the body 1180 of the heat transfer plate 190.

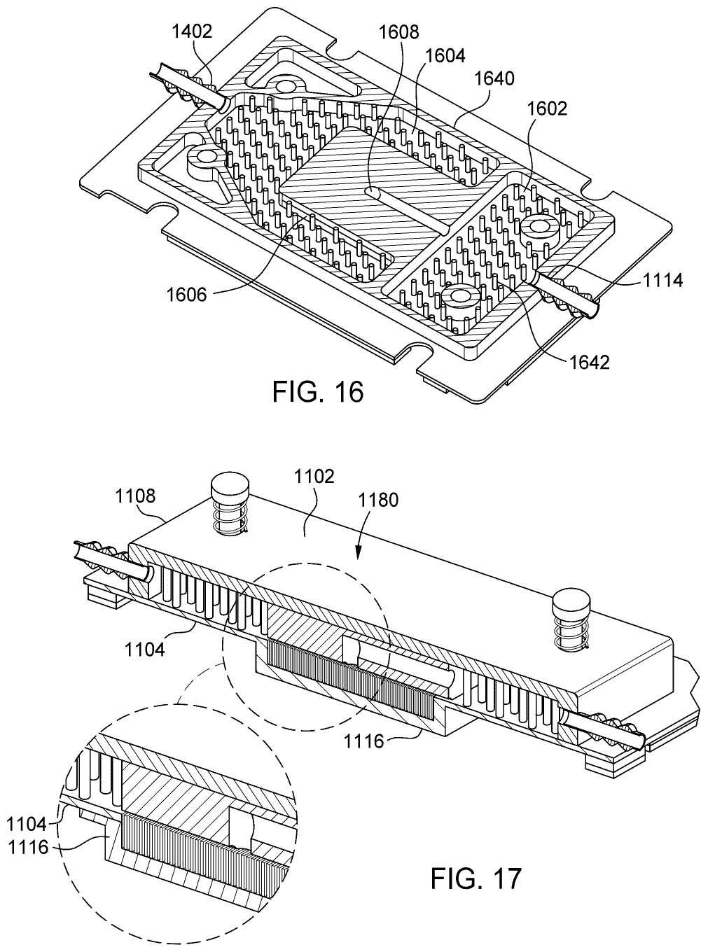

In FIGS. 16-19, the inlet cavity 1602, the outlet cavity 1604 and the center cavity 1606 that are formed in the body 1180 of the heat transfer plate 190 are more clearly illustrated. The center cavity 1606 is formed in the body 1180 between the inlet and outlet cavities 1602, 1604. The center cavity 1606 has an inlet 1608 coupled to an outlet of the inlet cavity 1602. The inlet 1608 of the center cavity disposed closer to a center of the center cavity than an edge of the center cavity. The inlet 1608 is connected to a channel 1810 formed over the center of a plurality of projections 1820 extending into the center cavity 1606. The plurality of projections 1820 may be formed as part of the pad 1116 or body 1180, and in one example, are braised to the pad 1116. In the example, the projections 1820 are fins having an orientation approximately 90 degrees perpendicular to the third and fourth sides 1104, 1110. The fins may also have a chevron orientation, the centers of which are aligned parallel the third and fourth sides 1104, 1110. The ends of the fins terminate at moats 1802, 1804 disposed on opposite sides of the center cavity 1606 closes to the third and fourth sides 1104, 1110 of the body 1180. Fluid flows out of the moats 1802, 1804 into the outlet cavity 1604. Optionally, a third moat may be formed extending between the moats 1802, 1804 along the edge of the center cavity 1606 closest the second side 1108.

Also as shown in FIGS. 16-19, a plurality of projections 1840 extend into the inlet cavity 1602, and a plurality of projections 1842 extend into the outlet cavity 1604. The projections 1840, 1842 may have a circular, oval, rectangular, or other cross section. The projections 1840, 1842 generally have a spacing that is less dense than a spacing of the projections 1802 extending into the center cavity 1606. Stated differently, the open area between projections 1840, 1842 of the inlet and outlet cavities 1602, 1604 is greater than the open area between the projections 1802 extending into the center cavity 1606.

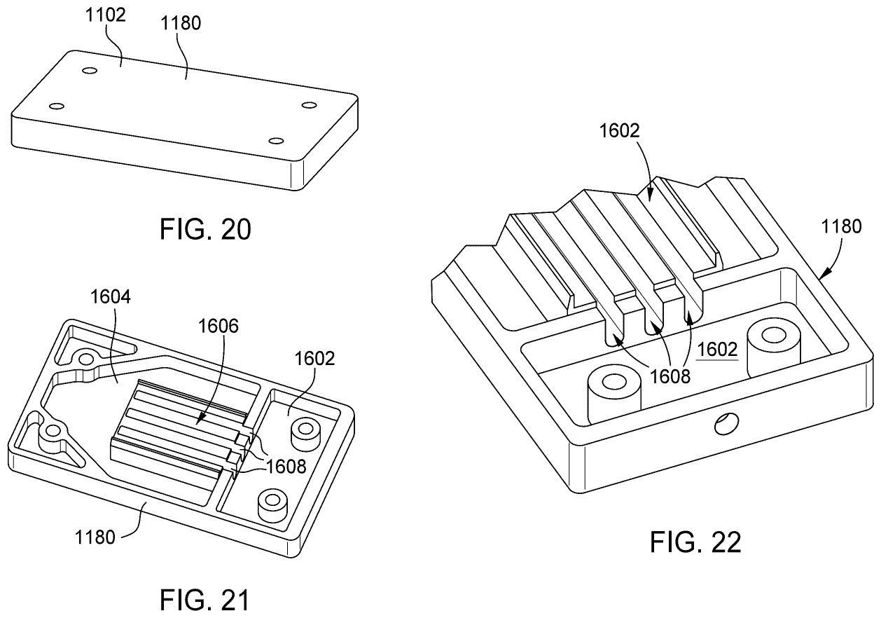

FIGS. 20-23 are various views of another example of a heat transfer plate 190 of the multi-cavity thermal control device 148 of FIG. 1. The heat transfer plate 190 of FIGS. 20-23 is generally the same as the heat transfer plate 190 describe above, except in that the center cavity 1606 has multiple inlets 1608 connecting the center cavity 1606 to the inlet cavity 1602.

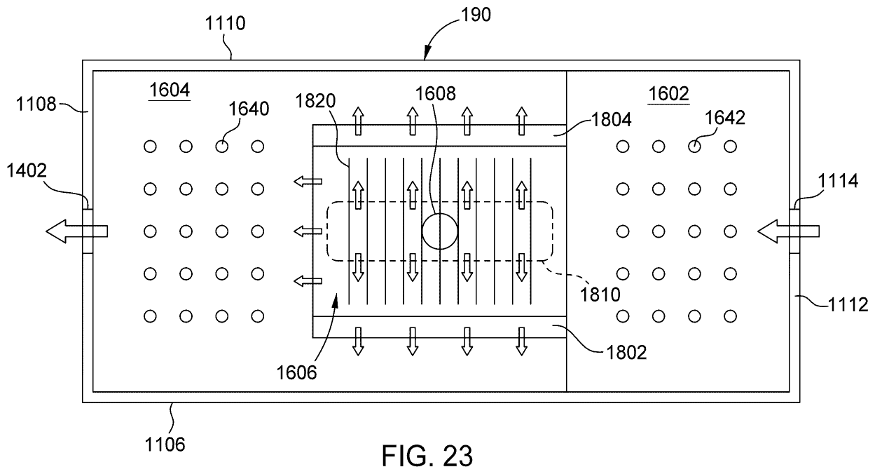

FIG. 23 is a schematic fluid flow schematic of the multi-cavity thermal control device 148 of FIG. 1. Coolant flows into the heat transfer plate 190 through the inlet port 1114 and enters the inlet cavity 1602. The coolant may be a vapor, gas liquid, or mixture of one or more of a vapor, gas and liquid. The coolant may be a single or two phase material. The coolant may also be a refrigerant. In one example, the coolant may be a two phase refrigerant such as a hydrochlorofluorocarbon (HCFC) refrigerant, for example Freon™M 123 and the like. The coolant in the inlet cavity 1602 then enters the center cavity 1606 through the inlet 1608. The coolant flows from the inlet 1608 into the channel 1810 formed over the center of the plurality of projections 1820 (shown as fins in FIG. 23). The coolant in the center cavity 1606 flow from the center of the center cavity 1606 towards the edges of the center cavity 1606 and into the moats 1802 1804 formed on opposite sides of the center cavity 1606. The coolant in the center cavity 1606 flowing towards the moats 1802 1804 is generally flowing towards the opposite sides 1106, 1110 of the heat transfer plate 190 rather than towards the sides 1108, 1112 where the inlet and outlets 1114, 1402 are located, beneficially increasing the resonance time of the coolant in the center cavity 1606. Coolant then exits the center cavity 1606 through the moats 1802 1804 into the outlet cavity 1604. From the outlet cavity 1604, coolant exits the heat transfer plate 190 through the outlet 1402.

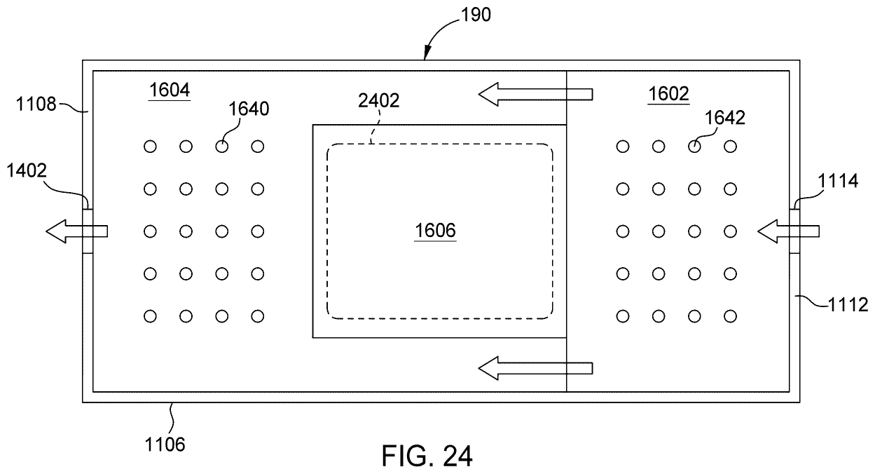

FIG. 24 is another schematic fluid flow schematic of the multi-cavity thermal control device 148 of FIG. 1 for examples wherein the center cavity 1606 is configured as a vapor chamber. In the example depicted in FIG. 24, coolant flow directly from the inlet cavity 1602 into the outlet cavity 1604 while bypassing the center cavity 1606, as the center cavity 1606 is sealingly isolated from the inlet and outlet cavities 1602, 1604. In this example, the inlet and outlet cavities 1602, 1604 may be combined as a single cavity. The center cavity 1606 contains a phase change material 2402. The phase change material 2402 suitable for use in IC device temperate control. The phase change material 2402 in a liquid phase in contact with a thermally conductive solid surface, i.e., the portion of the body 1180 below the center cavity 1606, turns into a vapor by absorbing heat from the top surface of the underlying compute die stack 130 through the pad 1116. The vapor (e.g., the phase change material 2402) then travels upwards inside the center cavity 1606 to the cold interface, i.e., the top surface 1102 of the body 1180, and condenses back into a liquid-releasing the latent heat into the body 1180, where the heat is then predominantly remove by the coolant flowing around the center cavity 1606 while moving from the inlet cavity 1602 to the outlet cavity 1604. The phase change material 2402 in liquid form then returns to the hot interface at the bottom of the center cavity 1606 through capillary action and/or gravity, and the cycle repeats. Due to the very high heat transfer coefficients for boiling and condensation, the center cavity 1606 effectively and efficiently conducts heat away from the underlying compute die stack 130 which advantageously improves the heat transfer performance and operation of the chip package assembly 100.

The above disclosed technology may also be expressed by one or more of the following non-limiting examples.

Example 1. A multi-cavity thermal control device including: a body having a top surface, a bottom surface, a first side facing away from a second side, and a third side facing away from a fourth side; an inlet cavity formed in the body proximate the first side and having an inlet port formed proximate the first side, the inlet port formed through an exterior surface of the body; an outlet cavity formed in the body proximate the second side and having an outlet port formed proximate the second side, the outlet port formed through the exterior surface of the body; and a center cavity formed in the body between the inlet and outlet cavities, the center cavity having an inlet coupled to an outlet of the inlet cavity, the inlet of the center cavity disposed closer to a center of the center cavity than an edge of the center cavity, the center cavity having an outlet configured to flow fluid into the outlet cavity.

Example 2. The multi-cavity thermal control device of Example 1, wherein the bottom surface further includes: a pad into which the center cavity extends, the pad projecting out from the bottom surface.

Example 3. The multi-cavity thermal control device of Example 1 further including: a first plurality of heat transfer projections extending into the center cavity.

Example 4. The multi-cavity thermal control device of Example 3, wherein the first plurality of heat transfer projections are fins that direct fluid entering the center cavity towards the third and fourth sides of the body.

Example 5. The multi-cavity thermal control device of Example 4, wherein the center cavity further includes: a first moat configured to receive fluid flowing out from between first ends of the fins that are closest to the third side of the body, the first moat having a long edge across which fluid from the first moat flows into the outlet cavity.

Example 6. The multi-cavity thermal control device of Example 5, wherein the center cavity further includes: a second moat configured to receive fluid flowing out from between second ends of the fins that are closest to the fourth side of the body, the second moat having a long edge across which fluid from the first moat flows into the outlet cavity.

Example 7. The multi-cavity thermal control device of Example 4, wherein the inlet cavity further includes: a first plurality of heat transfer projections extending into the inlet cavity, the first plurality of heat transfer projections having an open area therebetween that is greater than an open area between the fins.

Example 8. The multi-cavity thermal control device of Example 7, wherein the outlet cavity further includes: a second plurality of heat transfer projections extending into the outlet cavity, the second plurality of heat transfer projections having an open area therebetween that is greater than the open area between the fins.

Example 9. The multi-cavity thermal control device of Example 4, wherein the center cavity further includes: a mesh or porous material.

Example 10. An electronic device including: a chip package having a die side and a bottom side; and the multi-cavity thermal control device as described in any of Examples 1-9 coupled to the die side of the chip package.

Example 11. The electronic device of Example 10 further including: a top clamp plate disposed between the multi-cavity thermal control device and the chip package, the top clamp plate having a center window through which the chip package contacts the body of the multi-cavity thermal control device directly below the center cavity.

Example 12. The electronic device of Example 11, wherein the top clamp plate further includes at least one side window aligned directly above a power module of the chip package.

Example 13. The electronic device of Example 12 further including: a thermal interface material contacting the power module of the chip package and the body of the multi-cavity thermal control device to define a thermal path between the body and the power module, the thermal path passing through the side window.

Example 14. The electronic device of Example 11, wherein the chip package includes: a logic device including at least one processor die, the logic device contacting the body through the window; and an integrated circuit (IC) die disposed adjacent the logic device, the IC die contacting the top clamp plate through thermal interface material.

Example 15. The electronic device of Example 12 further including: a bottom clamp plate sandwiching the chip package to the top clamp plate.

Example 16. The electronic device of Example 15 further including: a plurality of springs urging the top and bottom clamp plates towards each other.

Example 17. The electronic device of Example 15, wherein the bottom clamp plate further includes: a window located to allow connection to a connection formed on a bottom surface of the chip package.

Example 18. The electronic device of Example 15, wherein the bottom clamp plate further includes: a bumper disposed between the bottom clamp plate and a bottom surface of the chip package.

Example 19. A multi-cavity thermal control device including: a body having a top surface, a bottom surface, a first side facing away from a second side, and a third side facing away from a fourth side; an inlet cavity formed in the body proximate the first side and having an inlet port formed proximate the first side, the inlet port formed through an exterior surface of the body; an outlet cavity formed in the body proximate the second side and having an outlet port formed proximate the second side, the outlet port formed through the exterior surface of the body, the inlet cavity fluidly connected to the outlet cavity; and a center cavity formed in the body between the inlet and outlet cavities, the center cavity sealingly isolated from the inlet and outlet cavities, the center cavity containing a phase change material.

Example 20. The multi-cavity thermal control device of Example 19, wherein the bottom surface further includes: a pad into which the center cavity extends, the pad projecting out from the bottom surface.

Example 21. The multi-cavity thermal control device of Example 19 further including: a first plurality of heat transfer projections extending into the center cavity.

Example 22. The multi-cavity thermal control device of Example 21, wherein the first plurality of heat transfer projections are fins that direct fluid entering the center cavity towards the third and fourth sides of the body.

Example 23. The multi-cavity thermal control device of Example 22, wherein the inlet cavity further includes: a first plurality of heat transfer projections extending into the inlet cavity, the first plurality of heat transfer projections having an open area therebetween that is greater than an open area between the fins.

Example 24. The multi-cavity thermal control device of Example 23, wherein the outlet cavity further includes: a second plurality of heat transfer projections extending into the outlet cavity, the second plurality of heat transfer projections having an open area therebetween that is greater than the open area between the fins.

Example 25. The multi-cavity thermal control device of Example 19, wherein the center cavity further includes: a mesh or porous material.

Example 26. An electronic device including: a chip package having a die side and a bottom side; and the multi-cavity thermal control device as described in any of Examples 19-25 coupled to the die side of the chip package.

Example 27. The electronic device of Example 26 further including: a top clamp plate disposed between the multi-cavity thermal control device and the chip package, the top clamp plate having a center window through which the chip package contacts the body of the multi-cavity thermal control device directly below the center cavity.

Example 28. The electronic device of Example 27, wherein the top clamp plate further includes at least one side window aligned directly above a power module of the chip package.

Example 29. The electronic device of Example 28 further including: a thermal interface material contacting the power module of the chip package and the body of the multi-cavity thermal control device to define a thermal path between the body and the power module, the thermal path passing through the side window.

Example 30. The electronic device of Example 28, wherein the chip package includes: a logic device including at least one processor die, the logic device contacting the body through the window; and an integrated circuit (IC) die disposed adjacent the logic device, the IC die contacting the top clamp plate through thermal interface material.

Example 31. The electronic device of Example 27 further including: a bottom clamp plate sandwiching the chip package to the top clamp plate.

Example 32. The electronic device of Example 31 further including: a plurality of springs urging the top and bottom clamp plates towards each other.

Example 33. The electronic device of Example 31, wherein the bottom clamp plate further includes: a window located to allow connection to a connection formed on a bottom surface of the chip package.

Example 34. The electronic device of Example 31, wherein the bottom clamp plate further includes: a bumper disposed between the bottom clamp plate and a bottom surface of the chip package.

While the foregoing is directed to embodiments of the present invention, other and further embodiments of the invention may be devised without departing from the basic scope thereof, and the scope thereof is determined by the claims that follow.

What is claimed is:

1. A multi-cavity thermal control device comprising:
a body having a top surface, a bottom surface, a first side facing away from a second side, and a third side facing away from a fourth side;
an inlet cavity formed in the body proximate the first side and having an inlet port formed proximate the first side, the inlet port formed through an exterior surface of the body;
an outlet cavity formed in the body proximate the second side and having an outlet port formed proximate the second side, the outlet port formed through the exterior surface of the body; and
a center cavity formed in the body between the inlet and outlet cavities, the center cavity having an inlet coupled to an outlet of the inlet cavity, the inlet of the center cavity disposed closer to a center of the center cavity than an edge of the center cavity, the center cavity having an outlet configured to flow fluid into the outlet cavity.

2. The multi-cavity thermal control device of claim 1, wherein the bottom surface further comprises:
a pad into which the center cavity extends, the pad projecting out from the bottom surface.

3. The multi-cavity thermal control device of claim 1 further comprising:
a first plurality of heat transfer projections extending into the center cavity.

4. The multi-cavity thermal control device of claim 3, wherein the first plurality of heat transfer projections are fins that direct fluid entering the center cavity towards the third and fourth sides of the body.

5. The multi-cavity thermal control device of claim 4, wherein the center cavity further comprises:
a first moat configured to receive fluid flowing out from between first ends of the fins that are closest to the third side of the body, the first moat having a long edge across which fluid from the first moat flows into the outlet cavity; and wherein the center cavity further comprises:
a second moat configured to receive fluid flowing out from between second ends of the fins that are closest to the fourth side of the body, the second moat having a long edge across which fluid from the first moat flows into the outlet cavity.

6. The multi-cavity thermal control device of claim 4, wherein the inlet cavity further comprises:
a first plurality of heat transfer projections extending into the inlet cavity, the first plurality of heat transfer projections having an open area therebetween that is greater than an open area between the fins; and wherein the outlet cavity further comprises:
a second plurality of heat transfer projections extending into the outlet cavity, the second plurality of heat transfer projections having an open area therebetween that is greater than the open area between the fins.

7. The multi-cavity thermal control device of claim 4, wherein the center cavity further comprises:
a mesh or porous material.

8. A multi-cavity thermal control device comprising:
a body having a top surface, a bottom surface, a first side facing away from a second side, and a third side facing away from a fourth side;
an inlet cavity formed in the body proximate the first side and having an inlet port formed proximate the first side, the inlet port formed through an exterior surface of the body;
an outlet cavity formed in the body proximate the second side and having an outlet port formed proximate the second side, the outlet port formed through the exterior surface of the body, the inlet cavity fluidly connected to the outlet cavity; and
a center cavity formed in the body between the inlet and outlet cavities, the center cavity sealingly isolated from the inlet and outlet cavities, the center cavity containing a phase change material.

9. The multi-cavity thermal control device of claim 8, wherein the bottom surface further comprises:
a pad into which the center cavity extends, the pad projecting out from the bottom surface.

10. The multi-cavity thermal control device of claim 8 further comprising:
a first plurality of heat transfer projections extending into the center cavity.

11. The multi-cavity thermal control device of claim 10, wherein the first plurality of heat transfer projections are fins that direct fluid entering the center cavity towards the third and fourth sides of the body.

12. The multi-cavity thermal control device of claim 11, wherein the inlet cavity further comprises:
a first plurality of heat transfer projections extending into the inlet cavity, the first plurality of heat transfer projections having an open area therebetween that is greater than an open area between the fins.

13. The multi-cavity thermal control device of claim 12, wherein the outlet cavity further comprises:
a second plurality of heat transfer projections extending into the outlet cavity, the second plurality of heat transfer projections having an open area therebetween that is greater than the open area between the fins.

14. The multi-cavity thermal control device of claim 8, wherein the center cavity further comprises:
a mesh or porous material.

15. An electronic device comprising:
a chip package having a die side and a bottom side; and
a multi-cavity thermal control device coupled to the die side of the chip package, the multi-cavity thermal control device comprising:
a body having a top surface, a bottom surface, a first side facing away from a second side, and a third side facing away from a fourth side;
an inlet cavity formed in the body proximate the first side and having an inlet port formed proximate the first side, the inlet port formed through an exterior surface of the body;
an outlet cavity formed in the body proximate the second side and having an outlet port formed proximate the second side, the outlet port formed through the exterior surface of the body; and
a center cavity formed in the body between the inlet and outlet cavities, wherein the center cavity:
(a) has an inlet coupled to an outlet of the inlet cavity, the inlet of the center cavity disposed closer to a center of the center cavity than an edge of the center cavity, the center cavity having an outlet configured to flow fluid into the outlet cavity; and/or
(b) is formed in the body between the inlet and outlet cavities, the center cavity sealingly isolated from the inlet and outlet cavities, the center cavity containing a phase change material.

16. The electronic device of claim 15 further comprising:
a top clamp plate disposed between the multi-cavity thermal control device and the chip package, the top clamp plate having a center window through which the chip package contacts the body of the multi-cavity thermal control device directly below the center cavity.

17. The electronic device of claim 16, wherein the top clamp plate further comprises at least one side window aligned directly above a power module of the chip package.

18. The electronic device of claim 17 further comprising:
a thermal interface material contacting the power module of the chip package and the body of the multi-cavity thermal control device to define a thermal path between the body and the power module, the thermal path passing through the side window.

19. The electronic device of claim 16, wherein the chip package comprises:
a logic device comprising at least one processor die, the logic device contacting the body through the center window; and
an integrated circuit (IC) die disposed adjacent the logic device, the IC die contacting the top clamp plate through thermal interface material.

20. The electronic device of claim 17 further comprising:
a bottom clamp plate sandwiching the chip package to the top clamp plate.
